(19) United States
(12) Patent Application Publication
(10) Pub. No.: US 2007/0235162 A1
(43) Pub. Date: Oct. 11, 2007

(54) RADIATOR

(76) Inventor: Chao-Chi Lin, Taichung (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/278,891

(22) Filed: Apr. 6, 2006

(51) Int. Cl. H05K 7/20

(52) U.S. Cl. 165/80.3; 361/704

(57) ABSTRACT

Disclosed is a radiator attachable to another radiator. The radiator includes a fin, a plurality of bent edges, a plurality of slots, a plurality of buckles and a plurality of lugs. The bent edges extend from the fin. The slots are defined in the fin, and each of them is located near a related one of the bent edges. Each of the buckles is formed within a related one of the slots, and includes a first section that can be pivoted without suffering damages and a second section extending from the first section at an angle. Each of the lugs includes a first section extending from a related one of the bent edges and a second section extending from the first section and defining an aperture for receiving the second section of a related one of the buckles of the other radiator.

### BACKGROUND OF INVENTION

1. Field of Invention

The present invention relates to a radiator and, more particularly, a radiator that can be assembled with and detached from another identical radiator without suffering damage.

2. Related Prior Art

Central processing units are used in computers to handle huge numbers of digital signals. The central processing units run at high rates on one hand and generate a lot of heat on the other hand. Lest heat is radiated from the central processing units quickly, the central processing units would become too hot and the rates would become too low. In some cases, the operation of the central process units would be stopped. In worst cases, the central processing units would be damaged.

To radiate the heat from the central processing units, a lot of radiators have been devised. The radiators may be made of extruded aluminum or cast metal. Such radiators are mature and encounter unbreakable bottlenecks. Instead of a single radiator made of extruded aluminum or cast metal, there is an on-going trend to use a stack of radiators for better radiating heat from a central processing unit.

Disclosed in Taiwanese Patent M275682 is a radiator 20 that can be assembled with another identical radiator. The radiator 20 includes two bent edges 22, two tabs 221 extending from each of the bent edges 22 and two slots 23 near each of the bent edges 22. The tabs 221 are biased from the bent edges 22 so that the tabs 221 can be aligned and inserted in the slots of the other identical radiator. Each of the tabs 221 is formed with a barb 2211 for hooking the other identical radiator when the tab 221 is completed inserted in one of the slots of the other identical radiator. It is however difficult to detach the radiator 20 from the other identical radiator 20 because of the barbs 2211.

The present invention is therefore intended to obviate or at least alleviate the problems encountered in prior art.

### SUMMARY OF INVENTION

According to the present invention, a radiator can be assembled with another radiator. The radiator includes a fin, a plurality of bent edges, a plurality of slots, a plurality of buckles and a plurality of lugs. The bent edges extend from the fin. The slots are defined in the fin, and each of them is located near a related one of the bent edges. Each of the buckles is formed within a related one of the slots, and includes a first section that can be pivoted without suffering damages and a second section extending from the first section at an angle. Each of the lugs includes a first section extending from a related one of the bent edges and a second section extending from the first section and defining an aperture for receiving the second section of a related one of the buckles of the other radiator.

An advantage of the radiator according to the present invention is that it can be detached from the other radiator without suffering damages since the buckles can be pivoted without suffering damages.

Another advantage of the radiator according to the present invention is that it can easily and firmly be assembled with the other radiator.

Other advantages and features of the present invention will become apparent from the following description referring to the drawings.

### BRIEF DESCRIPTION OF DRAWINGS

The present invention will be described through detailed illustration of the preferred embodiment referring to the drawings.

FIG. 1 is a perspective view of a stack of radiators according to the preferred embodiment of the present invention.

FIG. 2 is a perspective view showing one of the radiators detached from the other radiators shown in FIG. 1.

FIG. 3 is an enlarged partial cross-sectional view of one of the radiators shown in FIG. 2.

FIG. 4 is a top view of the stack of radiators shown in FIG. 1.

FIG. 5 is a cross-sectional view of the stack of radiators taken along a line 5-5 in FIG. 4.

FIG. 6 is an enlarged partial cross-sectional view of the stack of radiators shown in FIG. 5.

### DETAILED DESCRIPTION OF PREFERRED EMBODIMENT

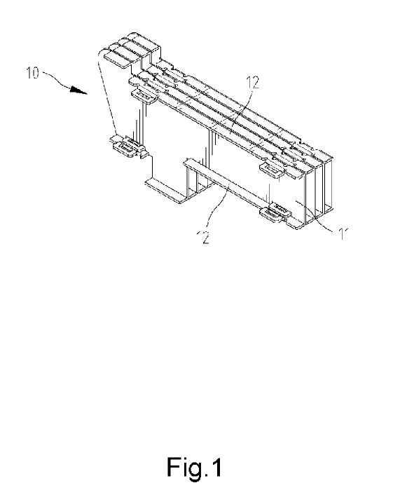

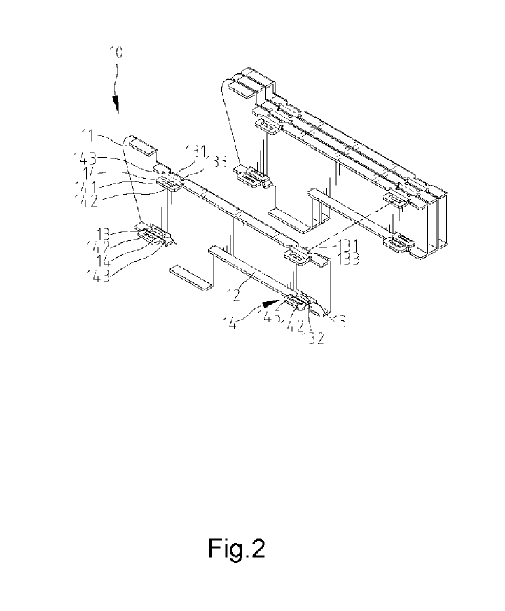

Referring to FIG. 1, there is shown a stack of radiators 10 according to the preferred embodiment of the present invention. The radiators 10 are assembled with one another. Referring to FIG. 2, the radiators 10 can be detached from one another if so desired.

For simplicity and clarity, the following description will be given to only one of the radiators 10, and the described radiator 10 is called “the radiator 10.”

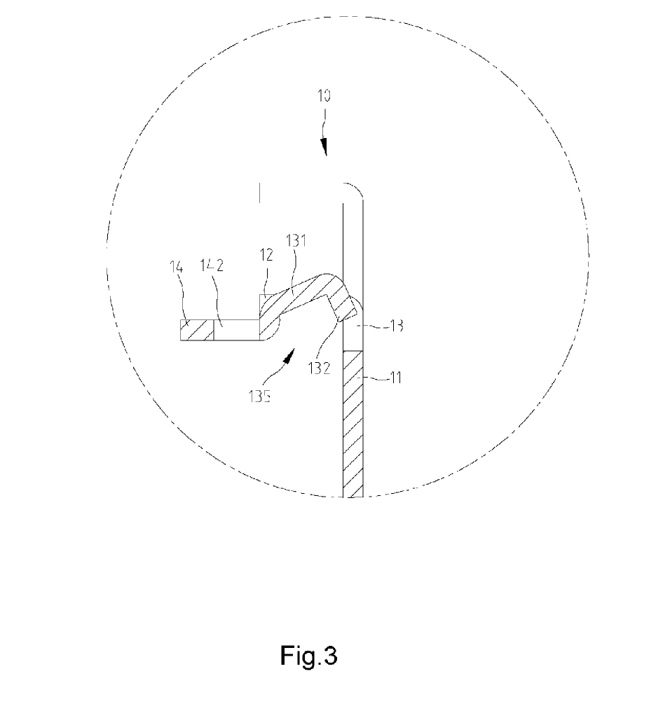

Referring to FIGS. 2 and 3, the radiator 10 includes a fin 11, a plurality of bent edges 12, a plurality of slots 13, a plurality of buckles 135 and a plurality of lugs 14.

The bent edges 12 extend from the fin 11 at the right angle.

Each of the slots 13 is defined in the fin 11 next to a related one of the bent edges 12. Each of the slots 13 can receive a related lug 14 of another identical radiator 10.

Each of the lugs 14 includes a first section 141 extending from the related one of the bent edges 12 and a second section 145 extending from the first section 141. The first section 141 is S-shaped so that the second section 145 is biased from the related one of the bent edges 12. The second section 145 of each of the lugs 14 defines an aperture 142 for receiving the second section 132 of a related buckle 135 of another radiator 10. Two cutouts 143 are defined in the related bent edge 12 beside the first section 141 of each of the lugs 14 to increase the resilience the lug 14.

Each of the buckles 135 is located within a related one of the slots 13 and oriented opposite to a related one of the lugs 14. Each of the bent edges 12 defines two cutouts 133 beside the related one of the buckles 135 to increase the resilience of the buckle 135. The buckle 135 includes a first section 131 extending at a small angle from the second section 145 of the lug 14 and a second section 132 extending from the first section 131 at the right angle.

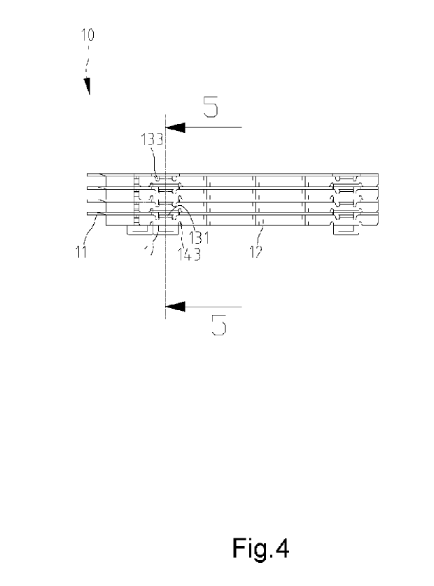

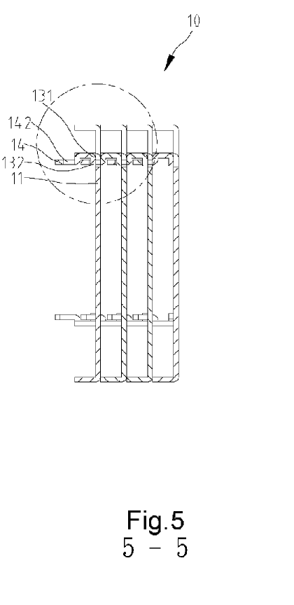

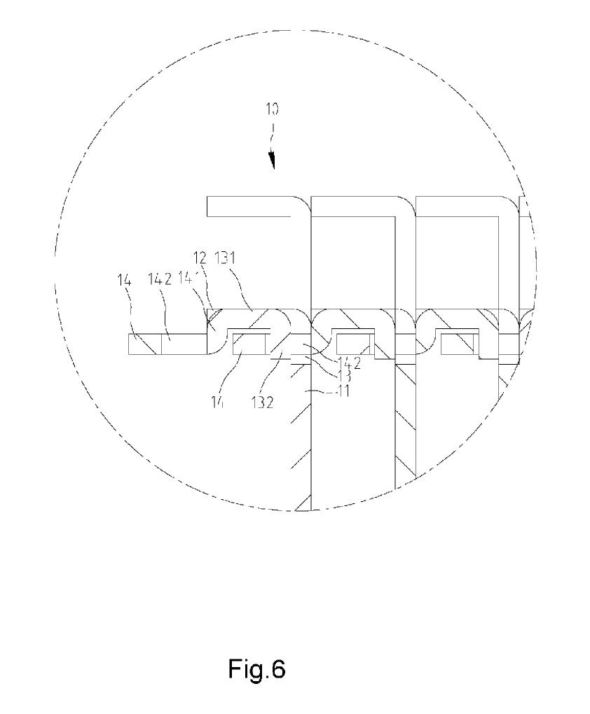

Referring to FIGS. 4 through 6, to assemble the radiator 10 with another radiator 10, the slots 13 thereof receive the lugs 14 of the other radiator 10. The first sections 131 of the buckles 135 of the radiator 10 are pivoted in a direction so that the second sections 132 of the same are inserted in the apertures 142 of the lugs 14 of the other radiator 10.

To detach the radiator 10 from the other radiator 10, the first sections of the buckles 135 of the radiator 10 are pivoted in an opposite direction so that the second sections 132 of the same are moved from the apertures 142 of the lugs 14 of the other radiator 10.

The radiator according to the present invention exhibits at least two advantages. Firstly, the buckles can easily be pivoted without suffering damages. Secondly, the radiator can easily and firmly be assembled with another radiator.

The present invention has been described through the illustration of the preferred embodiment. Those skilled in the art can derive variations from the preferred embodiment without departing from the scope of the present invention. Therefore, the preferred embodiment shall not limit the scope of the present invention defined in the claims.

What is claimed is:

1. A radiator attachable to another radiator, the radiator comprising:
a fin;
a plurality of bent edges extending from the fin;
a plurality of slots defined in the fin wherein each of the slots is located near a related one of the bent edges;
a plurality of buckles each formed within a related one of the slots, each of the buckles comprising a first section that can be pivoted without suffering damages and a second section extending from the first section at an angle; and
a plurality of lugs each comprising a first section extending from a related one of the bent edges and a second section extending from the first section and defining an aperture for receiving the second section of a related one of the buckles of the other radiator.

2. The radiator according to claim 1 wherein the angle between the first and second sections of each of the buckles is 90 degrees.

3. The radiator according to claim 1 wherein the first section of each of the lugs is S-shaped.

4. The radiator according to claim 1 wherein the second section of each of the lugs is flat.

5. The radiator according to claim 1 wherein each of the bent edges defines two cutouts beside the first section of the buckle.

6. The radiator according to claim 1 wherein each of the bent edges defines two cutouts beside the first section of the lug.
